(19) United States
(12) Patent Application Publication
(10) Pub. No.: US 2025/0160076 A1
(43) Pub. Date: May 15, 2025

(54) MICRO LIGHT EMITTING DIODE DISPLAY PANELS, METHODS OF MANUFACTURING THE SAME, AND DISPLAY DEVICES

(71) Applicant: Shenzhen China Star Optoelectronics Semiconductor Display Technology Co., Ltd., Shenzhen (CN)

(72) Inventor: Chunge YUAN, Shenzhen (CN)

(73) Assignee: Shenzhen China Star Optoelectronics Semiconductor Display Technology Co., Ltd., Shenzhen (CN)

(21) Appl. No.: 18/399,552

(22) Filed: Dec. 28, 2023

(30) Foreign Application Priority Data
Nov. 14, 2023 (CN) 202311520226.X

(51) Int. Cl. H01L 33/56; H01L 27/08; H01L 27/15

(52) U.S. Cl. CPC H10H 20/854; H10D 84/221; H10H 29/142

(57) ABSTRACT

Disclosed are a micro light emitting diode display panel, a method of manufacturing the same, and a display device. The micro light emitting diode display panel includes a driving circuit substrate, a plurality of micro light emitting diodes, and a protective layer. The plurality of micro light emitting diodes are disposed on a first surface of the driving circuit substrate. The protective layer is disposed at least on the first surface of the driving circuit substrate and covers the micro light emitting diodes. A material of the protective layer is selected from a Parylene system or an acrylic acid system.

### CROSS-REFERENCE TO RELATED APPLICATION

This application claims priority to and the benefit of Chinese Patent Application No. 202311520226.X, filed on Nov. 14, 2023, the disclosure of which is incorporated herein by reference in its entirety.

### TECHNICAL FIELD

The present disclosure relates to display technologies, and in particular, to micro light emitting diode display panels, methods of manufacturing a micro light emitting diode display panel, and display devices.

### BACKGROUND

After a micro light emitting diode (Micro LED) chip is transferred to a driving circuit substrate, the Micro LED chip needs to be packaged to avoid problems such as black spots caused by the Micro LED chip falling off, abnormal light emission caused by abrasion, dirt pollution, and electrode oxidation and corrosion caused by environmental water vapor/oxygen, thereby improving the lifetime of the Micro LED display panel and satisfying use requirements of the Micro LED display panel.

Currently, Micro LED chips are generally packaged using transparent optical adhesive or organic resin. In the process of packaging the Micro LED chip using transparent optical adhesive, it is necessary to perform heating and pressurization to enhance the filling effect of the optical adhesive, to perform vacuum defoaming to extract air bubbles caused by laminating and to perform UV curing, which result in a complicated process, high cost, and certain risk of bubbles. In addition, the optical adhesive material has poor blocking properties against water vapor and oxygen, resulting in insufficient packaging of a side of the display panel, water and oxygen can easily enter the panel from the side of the product, causing the device aging and reducing service life of the product. In the process of packaging the Micro LED chip using organic resin adhesive, it is necessary to reserve a wide process edge to prevent the adhesive from overflowing to areas outside the display panel. The subsequent process of removing the edge is complicated, for example, the organic resin is easy to crack when using a cutter wheel to cut the edge, and during grinding the edge of the glass after cutting, it is not easy to grind the edge of the organic resin material, or the resin is damaged and cracked when being stressed, which make it impossible to achieve the process requirements of a narrow frame and seamless splicing of narrow frames.

Therefore, it is necessary to provide a micro light emitting diode display panel, a method of manufacturing the same, and a display device, so as to improve the above defects.

### SUMMARY

An embodiment of the present disclosure provides a micro light emitting diode display panel including: a driving circuit substrate having a first surface and a second surface disposed oppositely; a plurality of micro light emitting diodes disposed on the first surface; a protective layer disposed at least on the first surface, the protective layer covers the plurality of micro light emitting diodes, and a material of the protective layer is selected from a Parylene system or an acrylic acid system.

An embodiment of the present disclosure further provides a method of manufacturing a micro light emitting diode display panel, to manufacture and form the micro light emitting diode display panel as described in the above embodiment. The method of manufacturing the micro light emitting diode display panel including: preparing a driving circuit substrate, the driving circuit substrate includes a first surface and a second surface disposed oppositely, and a plurality of micro light emitting diodes are disposed on the first surface; attaching a shielding layer to the second surface; depositing a protective material on the driving circuit substrate, the protective material covers the plurality of micro light emitting diodes, and the protective material is selected from a Parylene system or an acrylic acid system; removing the shielding layer and the protective material attached to the shielding layer to form the micro light emitting diode display panel.

According to the micro light emitting diode display panel provided in the embodiments described above, an embodiment of the present disclosure further provides a display device, and the display device includes the micro light emitting diode display panel provided in any one of the embodiments described above.

### BRIEF DESCRIPTION OF THE DRAWINGS

FIG. 1 is a schematic structural diagram of a first structure of a micro light emitting diode display panel provided by an embodiment of the present disclosure;

FIG. 2 is a schematic structural diagram of a second structure of a micro light emitting diode display panel provided by an embodiment of the present disclosure;

FIG. 3 is a schematic structural diagram of a third structure of a micro light emitting diode display panel provided by an embodiment of the present disclosure;

FIG. 4 is a schematic structural diagram of a fourth structure of a micro light emitting diode display panel provided by an embodiment of the present disclosure;

FIG. 5 is a schematic structural diagram of a fifth structure of a micro light emitting diode display panel provided by an embodiment of the present disclosure;

FIG. 6 is a schematic structural diagram of a structure of a display device provided by an embodiment of the present disclosure;

FIG. 7 is a flowchart of a method of manufacturing a micro light emitting diode display panel provided by an embodiment of the present disclosure;

FIG. 8 is a schematic flowchart of a method of manufacturing a micro light emitting diode display panel provided by an embodiment of the present disclosure;

FIG. 9 is a schematic flowchart of another method of manufacturing a micro light emitting diode display panel provided by an embodiment of the present disclosure;

FIG. 10 is a schematic flowchart of another method of manufacturing a micro light emitting diode display panel provided by an embodiment of the present disclosure;

FIG. 11 is a schematic flowchart of another method of manufacturing a micro light emitting diode display panel provided by an embodiment of the present disclosure;

FIG. 12 is a schematic flowchart of a method of manufacturing a display device provided by an embodiment of the present disclosure.

### DETAILED DESCRIPTION

With reference to the accompanying drawings, the following description of various embodiments is intended to exemplarily illustrate specific embodiments through which the present disclosure may be implemented. Directional terms mentioned in this disclosure, for example, “upper”, “lower”, “front”, “back”, “left”, “right”, “inner”, “outer”, “side”, and the like, are merely directions with reference to the accompanying drawings. Therefore, directional terms used herein are intended to explain and understand the present disclosure, and are not intended to limit the present disclosure. In the accompanying drawings, units with similar structures are represented by same reference numbers.

The present disclosure will be further described below in conjunction with the accompanying drawings and specific embodiments.

An embodiment of the present disclosure provide a micro light emitting diode display panel, which can improve the overall packaging performance of the micro light emitting diode display panel, while satisfying the requirements of a narrow frame and seamless splicing.

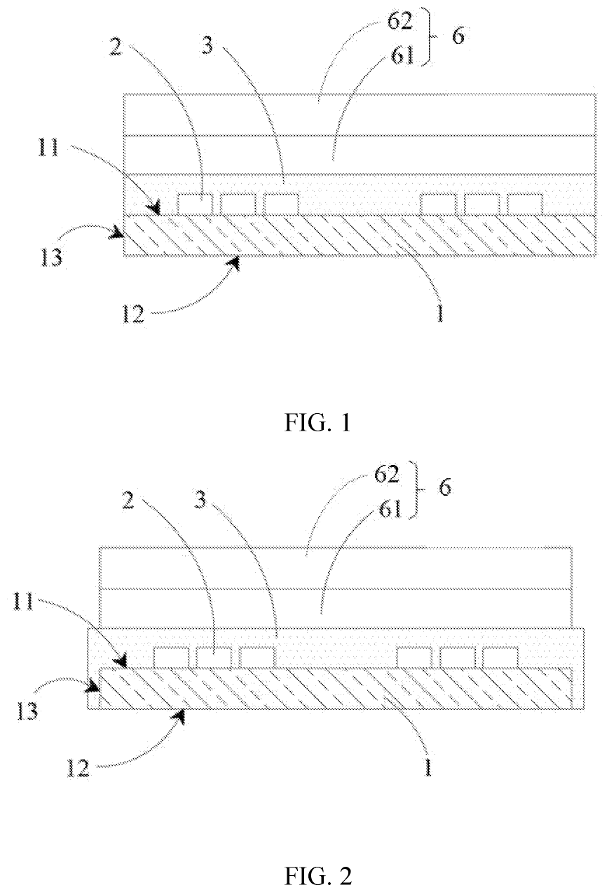

With reference to FIG. 1, FIG. 1 is a schematic structural diagram of a first structure of a micro light emitting diode display panel provided by an embodiment of the present disclosure. The micro light emitting diode display panel includes a driving circuit substrate 1, a plurality of micro light emitting diodes 2 and a protective layer 3.

In an embodiment of the present disclosure, the driving circuit substrate 1 includes a substrate (not shown) and a driving circuit layer (not shown) disposed on the substrate. The substrate is a flexible substrate, and a material of the flexible substrate may be but is not limited to polyimide. In some practical applications, the substrate may also be a rigid substrate, and the rigid substrate may be a glass substrate. A structure of the driving circuit layer can refer to the film layer structure of the driving circuit layer in the existing display panel, and is not limited herein.

The micro light emitting diode 2 is a Micro LED, and a size of its LED chip ranges from 1 micron to 100 microns.

The driving circuit substrate 1 includes a first surface 11 and a second surface 12 disposed oppositely, and the plurality of micro light emitting diodes 2 are disposed on the first surface 11. It should be noted that the first surface 11 does not refer to a surface of the substrate, but a surface of the driving circuit substrate 1 on which the plurality of micro light emitting diodes 2 are disposed, and the driving circuit substrate 1 is composed of the substrate and the driving circuit layer. There may be multiple pads on the driving circuit layer, and pins of the micro light emitting diode 2 are bonded and connected to corresponding pads on the driving circuit layer.

In some embodiments, the protective layer 3 is disposed at least on the first surface 11 of the driving circuit substrate 1, the protective layer 3 covers the plurality of micro light-emitting diodes 2, and a material of the protective layer 3 is selected from a Parylene system or an acrylic acid system.

Compared with packaging materials of optical adhesive or organic resin adhesive, materials of Parylene system or acrylic acid system can be deposited on the driving circuit substrate 1 through chemical vapor deposition or atomic layer deposition. By preparing the protective layer 3 using chemical vapor deposition or atomic layer deposition, it is possible to improve the gap filling ability of the protective layer 3 to the micro light emitting diodes 2, without being limited by the gap between adjacent micro light emitting diodes 2, so that the protective layer 3 can fully wrap the micro light emitting diodes 2, while no bubbles will be formed. Moreover, film thickness of the protective layer 3 is accurately controllable, and the film layer of the protective layer 3 has high flatness, which can save the vacuum defoaming process and facilitate subsequent attachment of film layers. Therefore, it can not only improve the packaging performance of the micro light emitting diode display panel, but also simplify the packaging process and reduce production costs. In addition, since materials of Parylene system or acrylic acid system deposited on the driving circuit substrate 1 will not overflow, there is no need to reserve a wide process edge to prevent the packaging material from overflowing, so as to reduce the frame width of the display panel, and thus satisfying requirements of a narrow frame and seamless splicing.

Specifically, the Parylene system includes at least one of parylene C, parylene D, parylene N, parylene F, or parylene HT. The acrylic acid system includes at least one of epoxy acrylate, polyurethane acrylate, pure acrylate, or polyester acrylate.

In an embodiment, as shown in FIG. 1, the protective layer 3 is disposed on the first surface 11 of the driving circuit substrate 1, and an orthographic projection of the protective layer 3 on the driving circuit substrate 1 completely overlaps the first surface 11. In some practical applications, the protective layer 3 may also cover the micro light emitting diodes 2 and part of the first surface 11, rather than completely covering the first surface 11.

The driving circuit substrate 1 may further include a side surface 13 disposed between the first surface 11 and the second surface 12, and the side surface 13 is connected to the first surface 11 and the second surface 12 respectively. In the embodiment shown in FIG. 1, the protective layer 3 is formed only on the first surface 11, and the protective layer 3 is not formed on the second surface 12 and the side surface 13.

It should be noted that the side surface 13 is a general term for the circumferential surface of the driving circuit substrate 1, and the side surface 13 may refer to only one surface, or may refer to multiple surfaces. For example, when the driving circuit substrate 1 is in the shape of a cylinder, the driving circuit substrate 1 has only one side surface, and the side surface 13 refers to one side surface of the driving circuit substrate 1. When the driving circuit substrate 1 is in the shape of a cube, the driving circuit substrate 1 has four side surfaces, and the side surface 13 refers to the four side surfaces of the driving circuit substrate 1.

In some embodiments, a thickness of the protective layer 3 is less than or equal to 50 microns.

In an embodiment, the thickness of the protective layer 3 is 30 microns.

In other embodiments, the thickness of the protective layer 3 is not limited to 30 microns described in the above embodiment, but can also be selected from any one of the following values: 5 microns, 10 microns, 20 microns, 40 microns or 50 microns.

Preferably, the thickness of the protective layer 3 is greater than or equal to 10 microns and less than or equal to 30 microns. At this thickness, it can not only improve the packaging performance of the micro light emitting diode display panel, but also ensure that the transmittance of the protective layer 3 is greater than 99%, thereby ensuring that the brightness of the micro light emitting diode display panel is not affected.

In some embodiments, the micro light emitting diode display panel further includes a functional layer 6 disposed on the surface of the protective layer 3, and an orthographic projection of the functional layer 6 on the driving circuit substrate 1 overlaps the first surface 11. The functional layer 6 may be, but is not limited to any one or a combination of a barrier film, an anti-scratch film, an anti-reflection film or an anti-fingerprint film.

In an embodiment, the functional layer 6 is a stacked structure composed of a barrier film 61 and an anti-reflection film 62.

FIG. 2 is a schematic structural diagram of a second structure of a micro light emitting diode display panel provided by an embodiment of the present disclosure. As shown in FIG. 2, this second structure is roughly the same as the first structure of the micro light emitting diode display panel shown in FIG. 1, and the difference is that: the protective layer 3 is continuously disposed on the first surface 11 and the side surface 13.

In the embodiment shown in FIG. 2, the protective layer 3 is not only disposed on the first surface 11 of the driving circuit substrate 1, but also disposed on the side surface 13. By disposing the protective layer 3 on the side surface 13 of the driving circuit substrate 1, the protective layer 3 can be used to prevent water and oxygen from invading into the interior of the micro light emitting diode display panel through the side of the driving circuit substrate 1, thereby further improving packaging performance of the micro light emitting diode display panel and extending service life of the micro light emitting diode display panel.

In an embodiment, the protective layer 3 is continuously disposed on the first surface 11, the side surface 13 and the second surface 12, that is, the protective layer 3 completely surrounds the driving circuit substrate 1 and the micro light emitting diodes 2, which can also achieve the effect of further improving packaging performance of the micro light emitting diode display panel and extending service life of the micro light emitting diode display panel.

In some embodiments, the micro light emitting diode display panel further includes a hydrophobic layer 4, the hydrophobic layer 4 is at least partially disposed on the surface of the protective layer 3 and covers the first surface 11 and the side surface 13.

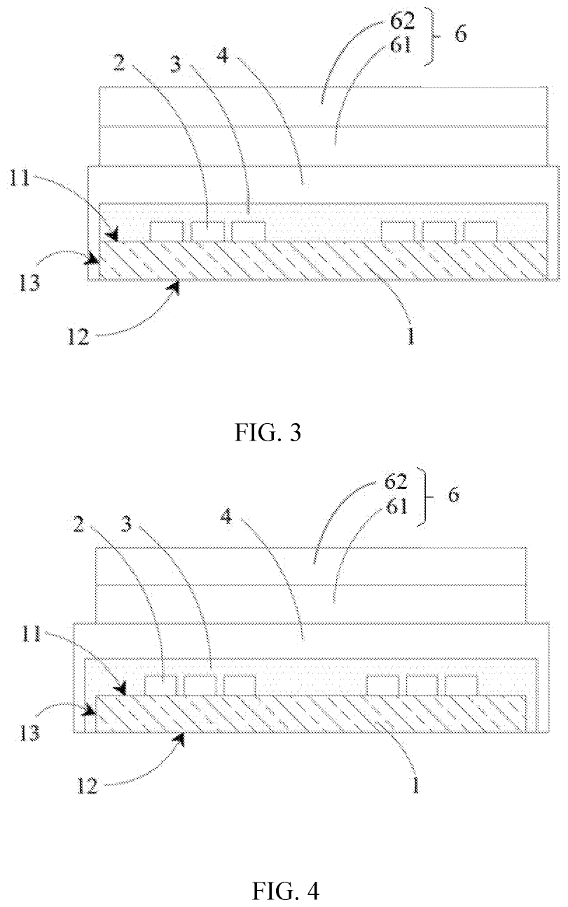

FIG. 3 is a schematic structural diagram of a third structure of a micro light emitting diode display panel provided by an embodiment of the present disclosure. As shown in FIG. 3, this third structure is roughly the same as the first structure of the micro light emitting diode display panel shown in FIG. 2, and the difference is that: the micro light emitting diode display panel further includes a hydrophobic layer 4 covering the first surface 11 and the side surface 13. Preferably, the hydrophobic layer 4 continuously covers the first surface 11 and the side surface 13.

In the embodiment shown in FIG. 3, the protective layer 3 is disposed on the first surface 11 of the driving circuit substrate 1 and covers the micro light emitting diodes 2, and the hydrophobic layer 4 is disposed on the surface of the protective layer 3 and the side surface 13 of the driving circuit substrate 1, that is, the hydrophobic layer 4 continuously covers the first surface 11 and the side surface 13 of the driving circuit substrate 1. In this structure, since the hydrophobic material has good waterproof performance, the hydrophobic layer 4 can be used to package and protect the side of the driving circuit substrate 1, so as to prevent water vapor from invading into the interior of the micro light emitting diode display panel through the side of the driving circuit substrate 1. Therefore, the packaging performance of the micro light emitting diode display panel can be further improved, and service life of the micro light emitting diode display panel can be extended.

In some embodiments, a material of the hydrophobic layer 4 is any one of highly hydrophobic carbon/fluorine organic materials.

In an embodiment, the material of the hydrophobic layer 4 is tetrafluoroethylene.

In some embodiments, a thickness of the hydrophobic layer 4 is greater than or equal to 0.05 microns and less than or equal to 5 microns.

In an embodiment, the thickness of the hydrophobic layer 4 is 2 microns.

In other embodiments, the thickness of the hydrophobic layer 4 is not limited to 2 microns described in the above embodiment, but can also be selected from any one of the following values: 0.05 microns, 0.1 microns, 0.5 microns, 1 micron, 3 microns, 4 microns or 5 microns.

Preferably, the thickness of the hydrophobic layer 4 is greater than or equal to 0.5 microns and less than or equal to 2 microns. At this thickness, it can not only improve the packaging performance of the micro light emitting diode display panel, but also make the transmittance of the hydrophobic layer 4 to be greater than 99%, thereby ensuring that the brightness of the micro light emitting diode display panel is not affected.

FIG. 4 is a schematic structural diagram of a fourth structure of a micro light emitting diode display panel provided by an embodiment of the present disclosure. As shown in FIG. 4, this fourth structure is roughly the same as the third structure of the micro light emitting diode display panel shown in FIG. 3, and the difference is that: the protective layer 3 is continuously disposed on the first surface 11 and the side surface 13.

In the embodiment shown in FIG. 4, the protective layer 3 and the hydrophobic layer 4 are continuously disposed on the first surface 11 and the side surface 13 of the driving circuit substrate 1. In this way, the protective layer 3 and the hydrophobic layer 4 can be used to form double protection for the side surface (i.e. side surface 13) of the driving circuit substrate 1, so as to further improve the packaging performance of the micro light emitting diode display panel and extend the service life of the micro light emitting diode display panel.

In some embodiments, the micro light emitting diode display panel further includes an inorganic packaging layer 5, and the inorganic packaging layer 5 is disposed on the surface of the hydrophobic layer 4.

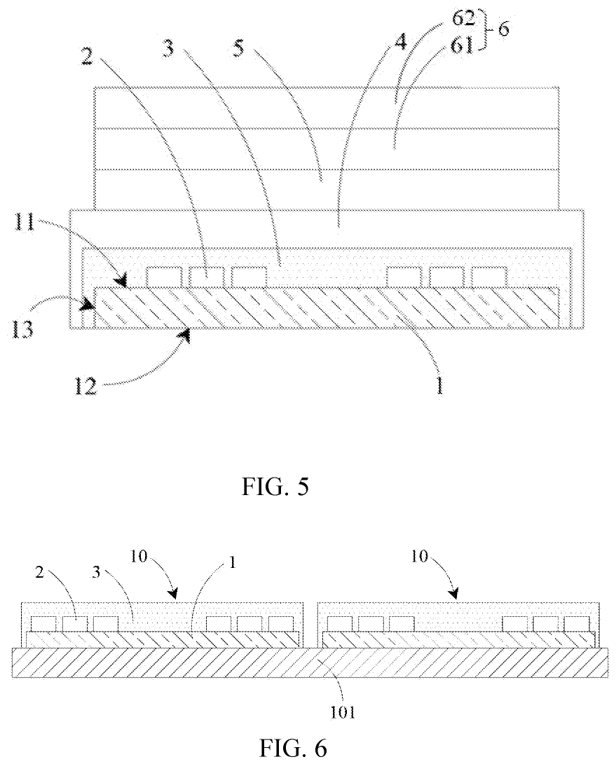

FIG. 5 is a schematic structural diagram of a fifth structure of a micro light emitting diode display panel provided by an embodiment of the present disclosure. As shown in FIG. 5, this fifth structure is roughly the same as the fourth structure of the micro light emitting diode display panel shown in FIG. 4, and the difference is that: the micro light emitting diode display panel further includes an inorganic packaging layer 5, which is disposed on the surface of the hydrophobic layer 4.

In the embodiment shown in FIG. 5, the inorganic packaging layer 5 is disposed on the surface of the hydrophobic layer 4, an orthographic projection of the inorganic packaging layer 5 on the driving circuit substrate 1 overlaps the first surface 11, and the inorganic packaging layer is not provided on the second surface 12 and the side surface 13. In this structure, since the inorganic packaging layer 5 has a good ability to block water and oxygen, the packaging performance of the micro light emitting diode display panel can be further improved.

In other embodiments, the inorganic packaging layer 5 can also be continuously disposed on the first surface 11 and the side surface 13, which can also further improve the packaging performance of the micro light emitting diode display panel.

In some embodiments, a material of the inorganic packaging layer 5 is selected from any one or a combination of silicon oxide, silicon nitride, silicon oxynitride, or aluminum oxide.

In an embodiment, the material of the inorganic packaging layer 5 is silicon oxide.

In some embodiments, a thickness of the inorganic packaging layer 5 is greater than or equal to 0.05 microns and less than or equal to 0.5 microns.

In an embodiment, the thickness of the inorganic packaging layer 5 is 0.1 microns.

In other embodiments, the thickness of the inorganic packaging layer 5 is not limited to 0.1 microns described in the above embodiment, but can also be selected from any one of the following values: 0.05 microns, 0.2 microns, 0.4 microns or 0.5 microns.

Preferably, the thickness of the inorganic packaging layer 5 is greater than or equal to 0.1 microns and less than or equal to 0.2 microns. At this thickness, it can not only improve the packaging performance of the micro light emitting diode display panel, but also ensure that the brightness of the micro light emitting diode display panel is not affected.

An embodiment of the present disclosure further provides a display device. The display device includes at least one micro light emitting diode display panel, and the micro light emitting diode display panel can be the micro light emitting diode display panel provided by any one of the above embodiments.

In some embodiments, the display device includes at least two micro light emitting diode display panels, and the at least two micro light emitting diode display panels are disposed in a spliced manner.

In an embodiment, as shown in FIG. 6 which is a schematic structural diagram of a structure of a display device provided by an embodiment of the present disclosure, the display device includes two micro light emitting diode display panels 10, and the two micro light emitting diode display panels 10 are disposed on a bearing substrate 101 in a spliced manner.

In practical applications, the number of micro light emitting diode display panels in the display device is not limited to two described in the above embodiment, but can also be three, four or more, and is not limited herein.

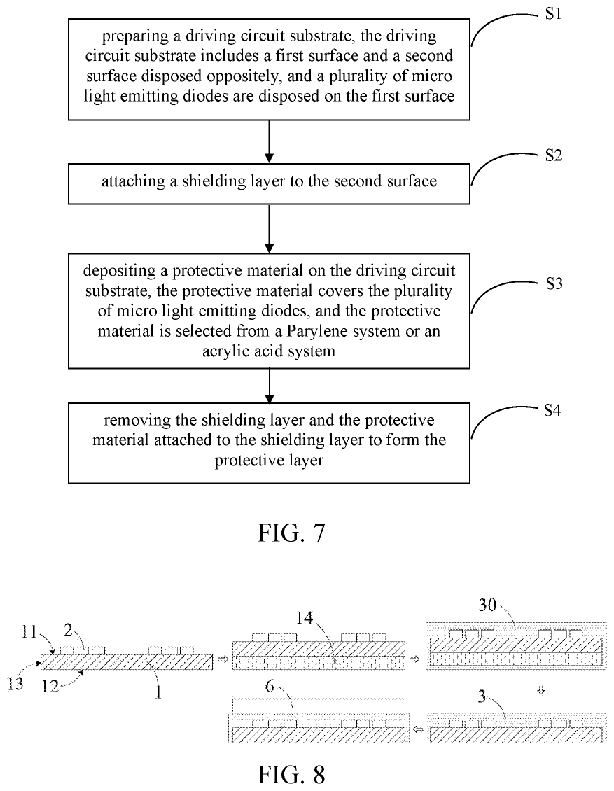

An embodiment of the present disclosure further provides a method of manufacturing a micro light emitting diode display panel, so as to manufacture the micro light emitting diode display panel as described above. With reference to FIG. 7 and FIG. 8, FIG. 7 is a flowchart of a method of manufacturing a micro light emitting diode display panel provided by an embodiment of the present disclosure, FIG. 8 is a schematic flowchart of a method of manufacturing a micro light emitting diode display panel provided by an embodiment of the present disclosure. The method of manufacturing a micro light emitting diode display panel includes the following steps.
Step S1: preparing a driving circuit substrate 1, the driving circuit substrate 1 includes a first surface 11 and a second surface 12 disposed oppositely, and a plurality of micro light emitting diodes 2 are disposed on the first surface 11;
Step S2: attaching a shielding layer 14 to the second surface 12;
Step S3: depositing a protective material 30 on the driving circuit substrate 1, the protective material 30 covers the plurality of micro light emitting diodes 2, and the protective material 30 is selected from a Parylene system or an acrylic acid system;
Step S4: removing the shielding layer 14 and the protective material attached to the shielding layer 14 to form a protective layer 3, and the protective layer 3 covers the first surface 11 and a side surface 13 of the driving circuit substrate 1.

In this embodiment, the micro light emitting diode display panel is a rigid micro light emitting diode display panel, the driving circuit substrate 1 includes a substrate and a driving circuit layer disposed on the substrate, and the substrate is a glass substrate. An active layer in the driving circuit layer may be an amorphous metal oxide semiconductor, for example, α-Si, IGZO, IGTO, and the like, and the transistor of the driving circuit substrate 1 may be a top gate structure or a back channel etching type structure.

In an embodiment, the shielding layer 14 is a temperature sensitive adhesive, and a viscosity of the shielding layer 14 is less than 10 N·s/m2. After attaching the shielding layer 14, the driving circuit substrate 1 is placed in a low temperature (ranging from −15° C. to 4° C.) environment for 10 minutes to 60 minutes.

In one embodiment, at step S3, the protective material 30 can be deposited on the surface of the driving circuit substrate 1 by means of chemical vapor deposition or atomic layer deposition, and the like.

At step S4, the protective material 30 in unnecessary areas is cut, and the shielding layer 14 and the protective material attached to the shielding layer 14 are removed by mechanical cutter wheel cutting or laser cutting to form the protective layer 3.

In an embodiment, the method of manufacturing a micro light emitting diode display panel further includes: attaching a functional layer 6 to the protective layer 3. The functional layer 6 may be selected from, but is not limited to, any one or a combination of a barrier film, an anti-scratch film, an anti-reflection film or an anti-fingerprint film.

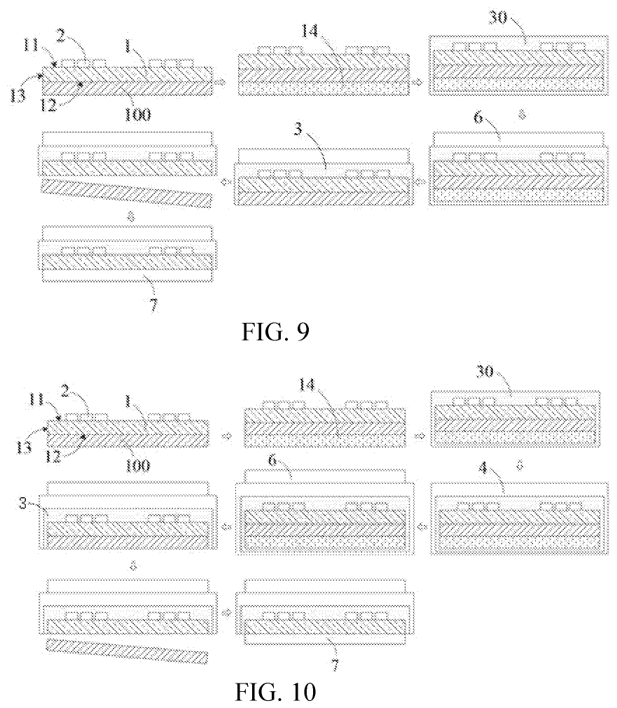

An embodiment of the present disclosure further provides another method of manufacturing a micro light emitting diode display panel, so as to manufacture a flexible micro light emitting diode display panel. With reference to FIG. 9, FIG. 9 is a schematic flowchart of another method of manufacturing a light emitting diode provided by an embodiment of the present disclosure, and the method of manufacturing a micro light emitting diode display panel includes the following steps.
Step S1: preparing a driving circuit substrate 1 on a glass substrate 100, the driving circuit substrate 1 includes a first surface 11 and a second surface 12 disposed oppositely, and a plurality of micro light emitting diodes 2 are disposed on the first surface 11;
Step S2: attaching a shielding layer 14 to a surface of the glass substrate 100 facing away from the driving circuit substrate 1;
Step S3: depositing a protective material 30 on the driving circuit substrate 1, the protective material 30 covers the micro light emitting diodes 2, and the protective material 30 is selected from a Parylene system or an acrylic acid system;
Step S4: attaching a functional layer 6 to a surface of the protective material 30, the functional layer 6 can be selected from, but not limited to any one or a combination of a barrier film, an anti-scratch film, an anti-reflection film or an anti-fingerprint film;
Step S5: removing the shielding layer 14 and the protective material attached to the shielding layer 14 to form a micro light emitting diode display panel.

In this embodiment, the micro light emitting diode display panel is a flexible micro light emitting diode display panel. The driving circuit substrate 1 includes a substrate and a driving circuit layer disposed on the substrate. The substrate is a flexible substrate, and a material of the substrate is polyimide. The active layer in the driving circuit layer may be an amorphous metal oxide semiconductor, such as α-Si, IGZO, IGTO, and the like, and the transistor of the driving circuit substrate 1 may be a top gate structure or a back channel etching type structure.

In an embodiment, the shielding layer 14 is a temperature sensitive adhesive, and the viscosity of the shielding layer 14 is less than 10 N·s/m2. After attaching the shielding layer 14, the driving circuit substrate 1 is placed in a low temperature (ranging from −15° C. to 4° C.) environment for 10 minutes to 60 minutes.

In an embodiment, at step S3, the protective material 30 can be deposited on the surface of the driving circuit substrate 1 by means of chemical vapor deposition or atomic layer deposition.

At step S5, the protective material 30 in unnecessary areas is cut, and the shielding layer 14 and the protective material attached to the shielding layer 14 are removed by mechanical cutter wheel cutting or laser cutting to form the protective layer 3.

In an embodiment, the method of manufacturing a micro light emitting diode display panel further includes: removing the glass substrate 100 by laser; and attaching a protective film 7 to the second surface 12 of the driving circuit substrate 1. The protective film 7 can be any one or a combination of a backplane, a PET film, a PEN film, a polarizer, a barrier film or an anti-scratch film.

An embodiment of the present disclosure further provides another method of manufacturing a micro light emitting diode display panel, so as to manufacture a flexible micro light emitting diode display panel. With reference to FIG. 10, FIG. 10 is a schematic flowchart of another method of manufacturing a light emitting diode display panel provided by an embodiment of the present disclosure, and the method of manufacturing a micro light emitting diode display panel includes the following steps.
Step S1: preparing a driving circuit substrate 1 on a glass substrate 100, the driving circuit substrate 1 includes a first surface 11 and a second surface 12 disposed oppositely, and a plurality of micro light emitting diodes 2 are disposed on the first surface 11;
Step S2: attaching a shielding layer 14 to a surface of the glass substrate 100 facing away from the driving circuit substrate 1;
Step S3: depositing a protective material 30 on the driving circuit substrate 1, the protective material 30 covers the micro light emitting diodes 2, and the protective material 30 is selected from a Parylene system or an acrylic acid system;
Step S4: forming a hydrophobic layer 4 on a surface of the protective material 30;
Step S5: attaching a functional layer 6 to a surface of the hydrophobic layer 4, the functional layer 6 can be selected from, but is not limited to, any one or a combination of a barrier film, an anti-scratch film, an anti-reflection film or an anti-fingerprint film;
Step S6: removing the shielding layer 14 and the protective material attached to the shielding layer 14 to form a protective layer 3.

In this embodiment, the micro light emitting diode display panel is a flexible micro light emitting diode display panel. The driving circuit substrate 1 includes a substrate and a driving circuit layer disposed on the substrate. The substrate is a flexible substrate and a material of the substrate is polyimide. The active layer in the driving circuit layer may be an amorphous metal oxide semiconductor, such as α-Si, IGZO, IGTO, and the like, and the transistor of the driving circuit substrate 1 may be a top gate structure or a back channel etching type structure.

In an embodiment, the shielding layer 14 is a temperature sensitive adhesive, and the viscosity of the shielding layer 14 is less than 10 N·s/m2. After attaching the shielding layer 14, the driving circuit substrate 1 is placed in a low temperature (ranging from −15° C. to 4° C.) environment for 10 minutes to 60 minutes.

In an embodiment, at step S3, the protective material 30 can be deposited on the surface of the driving circuit substrate 1 by means of chemical vapor deposition or atomic layer deposition.

At step S6, the protective material 30 in unnecessary areas is cut, and the shielding layer 14 and the protective material attached to the shielding layer 14 are removed by mechanical cutter wheel cutting or laser cutting to form the protective layer 3.

In an embodiment, the method of manufacturing a micro light emitting diode display panel further includes: removing the glass substrate 100 by laser; and attaching a protective film 7 to the second surface 12 of the driving circuit substrate 1. The protective film 7 can be any one or a combination of a backplane, a PET film, a PEN film, a polarizer, a barrier film or an anti-scratch film.

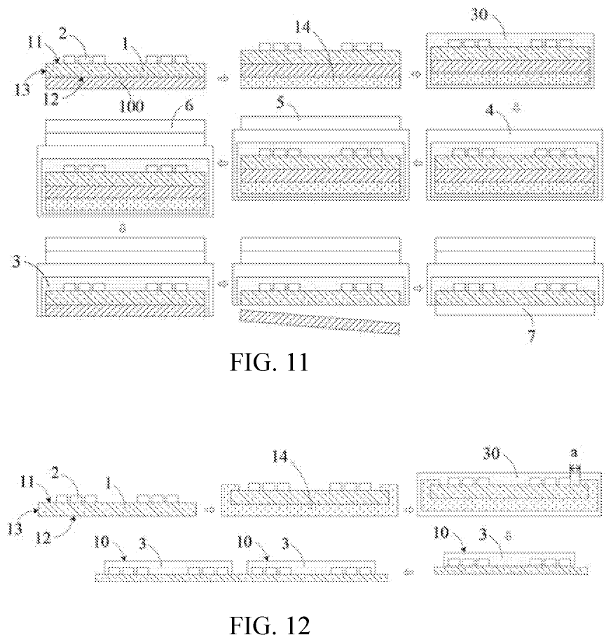

An embodiment of the present disclosure further provides another method of manufacturing a micro light emitting diode display panel, so as to manufacture a flexible micro light emitting diode display panel. With reference to FIG. 11, FIG. 11 is a schematic flowchart of another method of manufacturing a light emitting diode display panel provided by an embodiment of the present disclosure, and the method of manufacturing a micro light emitting diode display panel includes the following steps.
Step S1: preparing a driving circuit substrate 1 on a glass substrate 100, the driving circuit substrate 1 includes a first surface 11 and a second surface 12 disposed oppositely, and a plurality of micro light emitting diodes 2 are disposed on the first surface 11;
Step S2: attaching a shielding layer 14 to a surface of the glass substrate 100 facing away from the driving circuit substrate 1;
Step S3: depositing a protective material 30 on the driving circuit substrate 1, the protective material 30 covers the micro light emitting diodes 2, and the protective material 30 is selected from a Parylene system or an acrylic acid system;
Step S4: forming a hydrophobic layer 4 on a surface of the protective material 30;
Step S5: forming an inorganic packaging layer 5 on a surface of the hydrophobic layer 4;
Step S6: attaching a functional layer 6 to a surface of the inorganic packaging layer 5, the functional layer 6 can be selected from but not limited to any one or a combination of a barrier film, an anti-scratch film, an anti-reflection film or an anti-fingerprint film;
Step S7: removing the shielding layer 14 and the protective material attached to the shielding layer 14 to form the protective layer 3.

In this embodiment, the micro light emitting diode display panel is a flexible micro light emitting diode display panel. The driving circuit substrate 1 includes a substrate and a driving circuit layer disposed on the substrate. The substrate is a flexible substrate and a material of the substrate is polyimide. The active layer in the driving circuit substrate may be an amorphous metal oxide semiconductor, such as α-Si, IGZO, IGTO, and the like, and the transistor of the driving circuit substrate 1 may be a top gate structure or a back channel etching type structure.

In an embodiment, the shielding layer 14 is a temperature sensitive adhesive, and the viscosity of the shielding layer 14 is less than 10 N·s/m2. After attaching the shielding layer 14, the driving circuit substrate 1 is placed in a low temperature (ranging from −15° C. to 4° C.) environment for 10 minutes to 60 minutes.

In an embodiment, at step S3, the protective material 30 can be deposited on the surface of the driving circuit substrate 1 by means of chemical vapor deposition or atomic layer deposition.

At step S7, the protective material 30 in unnecessary areas is cut, and the shielding layer 14 and the protective material attached to the shielding layer 14 are removed by mechanical cutter wheel cutting or laser cutting to form the protective layer 3.

In an embodiment, the method of manufacturing a micro light emitting diode display panel further includes: removing the glass substrate 100 by laser; and attaching a protective film 7 to the second surface 12 of the driving circuit substrate 1. The protective film 7 can be any one or a combination of a backplane, a PET film, a PEN film, a polarizer, a barrier film or an anti-scratch film.

An embodiment of the present disclosure further provides a method of manufacturing a display device, so as to manufacture the display device described above. With reference to FIG. 12, FIG. 12 is a schematic flowchart of a method of manufacturing a display device provided by an embodiment of the present disclosure, and the method of manufacturing a micro light emitting diode display device includes the following steps.
Step S1: preparing a driving circuit substrate 1, the driving circuit substrate 1 includes a first surface 11 and a second surface 12 disposed oppositely, and a plurality of micro light emitting diodes 2 are disposed on the first surface 1;
Step S2: attaching a shielding layer 14 to the second surface 12, a side surface 13 and part of the first surface 11, and a distance “a” between the shielding layer 14 disposed on part of the first surface 11 and the micro light emitting diode 2 closest to the shielding layer 14 is greater than or equal to 10 microns; in some practical applications, the distance “a” can be set according to actual requirements, and is not limited herein;
Step S3: depositing a protective material 30 on the driving circuit substrate 1, the protective material 30 covers the micro light emitting diodes 2, and the protective material 30 is selected from a Parylene system or an acrylic acid system;
Step S4: removing the shielding layer 14 and the protective material attached to the shielding layer 14 to form the protective layer 3;
Step S5: cutting and grinding the driving circuit substrate 1 according to a required size to obtain a micro light emitting diode display panel 10;
Step S6: seamlessly splicing at least two micro light emitting diode display panels 10 according to requirements to obtain the display device.

In this embodiment, the micro light emitting diode display panel is a rigid micro light emitting diode display panel. The driving circuit substrate 1 includes a substrate and a driving circuit layer disposed on the substrate, and the substrate is a glass substrate. The active layer in the driving circuit layer may be an amorphous metal oxide semiconductor, such as α-Si, IGZO, IGTO, and the like, and the transistor of the driving circuit substrate 1 may be a top gate structure or a back channel etching type structure.

In an embodiment, the shielding layer 14 is a temperature sensitive adhesive, and the viscosity of the shielding layer 14 is less than 10 N·s/m2. After attaching the shielding layer 14, the driving circuit substrate 1 is placed in a low temperature (ranging from −15° C. to 4° C.) environment for 10 minutes to 60 minutes.

In an embodiment, at step S3, the protective material 30 can be deposited on the surface of the driving circuit substrate 1 by means of chemical vapor deposition or atomic layer deposition.

At step S4, the protective material 30 in unnecessary areas is cut, and the shielding layer 14 and the protective material attached to the shielding layer 14 are removed by mechanical cutter wheel cutting or laser cutting to form the protective layer 3.

In an embodiment, a distance between any adjacent two micro light emitting diodes in the micro light emitting diode display panel may be less than 0.5 millimeters, and a frame width of the micro light emitting diode display panel is less than 40 microns.

Beneficial effects of embodiments of the present disclosure: embodiments of the present disclosure provide a micro light emitting diode display panel, a method of manufacturing the same, and a display device. The micro light emitting diode display panel includes a driving circuit substrate, a plurality of micro light emitting diodes, and a protective layer. The plurality of micro light emitting diodes are disposed on a first surface of the driving circuit substrate. The protective layer is disposed at least on the first surface of the driving circuit substrate and covers the micro light emitting diodes, and a material of the protective layer is selected from a Parylene system or an acrylic acid system. By forming the protective layer using depositing materials of a Parylene system or an acrylic acid system, there is a strong ability to fill the gap between micro light emitting diodes, without being limited by the gap between micro light emitting diodes, which are not only conducive to achieving the effect of a narrow frame and seamless splicing, but also improve the overall packaging performance of the micro light emitting diode display panel.

In summary, although the present disclosure has been disclosed as above with preferred embodiments, the above preferred embodiments are not intended to limit the present disclosure. Those skilled in the art can make various modifications and variations without departing from the spirit and scope of the present disclosure. Therefore, the protection scope of this disclosure is based on the scope defined by the appended claims.

What is claimed is:

1. A micro light emitting diode display panel comprising:
a driving circuit substrate having a first surface and a second surface disposed oppositely;
a plurality of micro light emitting diodes disposed on the first surface;
a protective layer disposed at least on the first surface, wherein the protective layer covers the plurality of micro light emitting diodes, and a material of the protective layer is selected from a Parylene system or an acrylic acid system.

2. The micro light emitting diode display panel according to claim 1, wherein the driving circuit substrate further comprises a side surface, the side surface is disposed between the first surface and the second surface, and the side surface is connected to the first surface and the second surface respectively, the protective layer is continuously disposed on the first surface and the side surface.

3. The micro light emitting diode display panel according to claim 2, wherein a thickness of the protective layer is less than or equal to 50 microns.

4. The micro light emitting diode display panel according to claim 1, wherein the micro light emitting diode display panel further comprises a hydrophobic layer, and the hydrophobic layer is at least partially disposed on a surface of the protective layer;
wherein the driving circuit substrate further comprises a side surface, the side surface is disposed between the first surface and the second surface, and the side surface is connected to the first surface and the second surface respectively, and the hydrophobic layer covers the first surface and the side surface.

5. The micro light emitting diode display panel according to claim 4, wherein a thickness of the hydrophobic layer is greater than or equal to 0.05 microns and less than or equal to 5 microns.

6. The micro light emitting diode display panel according to claim 4, wherein the micro light emitting diode display panel further comprises an inorganic packaging layer, and the inorganic packaging layer is disposed on a surface of the hydrophobic layer.

7. The micro light emitting diode display panel according to claim 1, wherein the Parylene system comprises at least one of parylene C, parylene D, parylene N, and parylene F, or parylene HT;
the acrylic acid system comprises at least one of epoxy acrylate, polyurethane acrylate, pure acrylate, or polyester acrylate.

8. The micro light emitting diode display panel according to claim 2, wherein the micro light emitting diode display panel further comprises a hydrophobic layer, and the hydrophobic layer is at least partially disposed on a surface of the protective layer, and the hydrophobic layer covers the first surface and the side surface.

9. The micro light emitting diode display panel according to claim 3, wherein the micro light emitting diode display panel further comprises a hydrophobic layer, and the hydrophobic layer is at least partially disposed on a surface of the protective layer, and the hydrophobic layer covers the first surface and the side surface.

10. The micro light emitting diode display panel according to claim 1, wherein a thickness of the protective layer is greater than or equal to 10 microns and less than or equal to 30 microns.

11. The micro light emitting diode display panel according to claim 4, wherein a thickness of the hydrophobic layer is greater than or equal to 0.5 microns and less than or equal to 2 microns.

12. The micro light emitting diode display panel according to claim 6, wherein the inorganic packaging layer is continuously disposed on the first surface and the side surface.

13. The micro light emitting diode display panel according to claim 6, wherein a thickness of the inorganic packaging layer is greater than or equal to 0.1 microns and less than or equal to 0.2 microns.

14. A method of manufacturing a micro light emitting diode display panel, wherein the micro light emitting diode display panel comprising: a driving circuit substrate having a first surface and a second surface disposed oppositely; a plurality of micro light emitting diodes disposed on the first surface; and a protective layer disposed at least on the first surface, wherein the protective layer covers the plurality of micro light emitting diodes;
wherein the method of manufacturing a micro light emitting diode display panel comprises:
preparing the driving circuit substrate;
attaching a shielding layer to the second surface;
depositing a protective material on the driving circuit substrate and the shielding layer, wherein the protective material covers the plurality of micro light emitting diodes, and the protective material is selected from a Parylene system or an acrylic acid system;
removing the shielding layer and the protective material attached to the shielding layer to form the protective layer.

15. The method of manufacturing a micro light emitting diode display panel according to claim 14, wherein the driving circuit substrate further comprises a side surface, the side surface is disposed between the first surface and the second surface, and the side surface is connected to the first surface and the second surface respectively;
the attaching the shielding layer to the second surface further comprises:
attaching the shielding layer to the second surface, the side surface and a part of the first surface.

16. A display device comprising at least one micro light emitting diode display panel, wherein the at least one micro light emitting diode display panel comprises:
a driving circuit substrate having a first surface and a second surface disposed oppositely;
a plurality of micro light emitting diodes disposed on the first surface;
a protective layer disposed at least on the first surface, wherein the protective layer covers the plurality of micro light emitting diodes, and a material of the protective layer is selected from a Parylene system or an acrylic acid system.

17. The display device according to claim 16, wherein the display device comprises at least two micro light emitting diode display panels, and the at least two micro light emitting diode display panels are disposed in a spliced manner.

18. The display device according to claim 16, wherein the driving circuit substrate further comprises a side surface, the side surface is disposed between the first surface and the second surface, and the side surface is connected to the first surface and the second surface respectively, the protective layer is continuously disposed on the first surface and the side surface.

19. The display device according to claim 16, wherein the micro light emitting diode display panel further comprises a hydrophobic layer, and the hydrophobic layer is at least partially disposed on a surface of the protective layer;
wherein the driving circuit substrate further comprises a side surface, the side surface is disposed between the first surface and the second surface, and the side surface is connected to the first surface and the second surface respectively, and the hydrophobic layer covers the first surface and the side surface.

20. The display device according to claim 19, wherein the micro light emitting diode display panel further comprises an inorganic packaging layer, and the inorganic packaging layer is disposed on a surface of the hydrophobic layer.
